(19) United States
(12) Patent Application Publication
(10) Pub. No.: US 2018/0197924 A1
(43) Pub. Date: Jul. 12, 2018

(54) TOUCH SENSOR AND DISPLAY DEVICE HAVING TOUCH SENSOR

(71) Applicant: Japan Display Inc., Tokyo (JP)

(72) Inventors: Yusuke TADA, Tokyo (JP); Hajime AKIMOTO, Tokyo (JP)

(21) Appl. No.: 15/852,025

(22) Filed: Dec. 22, 2017

(30) Foreign Application Priority Data
Jan. 11, 2017 (JP) 2017-002481

(51) Int. Cl. H01L 27/32; H01L 51/00; H01L 51/52; H01L 51/56; G06F 3/044

(52) U.S. Cl. CPC H01L 27/323; H01L 51/0097; H01L 27/3272; H01L 27/3216; H01L 51/5253; G06F 2203/04111; H01L 27/3218; G06F 3/044; H01L 2251/5338; H01L 2227/323; G06F 2203/04112; H01L 51/56

(57) ABSTRACT

A display device in an embodiment according to the present invention includes a substrate having flexibility, and a plurality of touch electrodes arranged above the substrate. Each of the plurality of touch electrodes has a mesh structure, the mesh structure includes a first conducting part and a second conducting part, the first conducting part extends in a first direction, the second conducting part extends in a second direction intersecting a direction orthogonal to the first direction, and at least one angle between the first direction and the second direction is less than 90 degrees.

### CROSS REFERENCE TO RELATED APPLICATIONS

This application is based upon and claims the benefit of priority from the prior Japanese Patent Application No. 2017-002481, filed on Jan. 11, 2017, the entire contents of which are incorporated herein by reference.

### FIELD

One embodiment of the present invention is related to a display device mounted with a touch sensor. For example, the present invention is related to an organic EL (electroluminescence) display device mounted with a touch sensor.

### BACKGROUND

A touch sensor is known as an interface for a user to input information to a display device. By installing the touch sensor to overlap with the screen of the display device, it is possible for the user to operate input buttons and icons which are displayed on the screen, and easily input information to the display device.

For example, in Japanese Laid-open Patent No. 2016-076146, a touch panel is disclosed formed by arranging a plurality of wiring patterns arranged parallel to a horizontal direction and a plurality of wiring patterns arranged parallel to a vertical direction in a matrix shape on the front and rear of a base member, the touch panel is wired to an electrode part from an end part of a matrix by each lead wire and the base member is bent at least one of the lead wire parts, wherein the lead wire has an inclination with respect to a bend line at the bent part.

### SUMMARY

A display device in an embodiment according to the present invention includes a substrate having flexibility, and a plurality of touch electrodes arranged above the substrate. Each of the plurality of touch electrodes has a mesh structure, the mesh structure includes a first conducting part and a second conducting part, the first conducting part extends in a first direction, the second conducting part extends in a second direction intersecting a direction orthogonal to the first direction, and at least one angle between the first direction and the second direction is less than 90 degrees.

A display device in an embodiment according to the present invention includes a substrate having flexibility, a display region above the substrate and including a plurality of sub-pixels arranged in a matrix, each having a light emitting element, an insulating layer covering the display region, and a plurality of touch electrodes above the insulating layer. Each of the plurality of touch electrodes has a mesh structure, the mesh structure includes a first conducting part and a second conducting part, the first conducting part extends in a first direction, the second conducting part extends in a second direction intersecting a direction orthogonal to the first direction, the first conducting part and the second conducting part are arranged on the outer side of the light emitting element of each of the plurality of the subpixels in a plan view, and at least one angle between the first direction and the second direction is less than 90 degrees.

### BRIEF DESCRIPTION OF DRAWINGS

FIG. 1 is a plan view schematic diagram of a display device of an embodiment of the present invention;

FIG. 2 is a schematic diagram showing a structure of a display device of an embodiment of the present invention;

FIG. 3A, FIG. 3B and FIG. 3C are schematic diagrams showing a pixel of a display device of an embodiment of the present invention;

FIG. 4 is a plan view schematic diagram of a touch electrode of a display device of an embodiment of the present invention;

FIG. 5A and FIG. 5B are cross-sectional schematic diagrams of a touch electrode of a display device of an embodiment of the present invention;

FIG. 6 is a plan view schematic diagram of a touch electrode of a display device of an embodiment of the present invention;

FIG. 7A and FIG. 7B are cross-sectional schematic diagrams of a touch electrode of a display device of an embodiment of the present invention;

FIG. 8 is a cross-sectional schematic diagram of a display device of an embodiment of the present invention;

FIG. 9 is a layout diagram of a touch electrode and a pixel of a display device of an embodiment of the present invention;

FIG. 10 is a layout diagram of a touch electrode and a pixel of a display device of an embodiment of the present invention;

FIG. 11A and FIG. 11B are cross-sectional schematic diagrams for explaining a manufacturing method of a display device of an embodiment of the present invention;

FIG. 12A and FIG. 12B are cross-sectional schematic diagrams for explaining a manufacturing method of a display device of an embodiment of the present invention;

FIG. 13A and FIG. 13B are cross-sectional schematic diagrams for explaining a manufacturing method of a display device of an embodiment of the present invention;

FIG. 14A and FIG. 14B are cross-sectional schematic diagrams for explaining a manufacturing method of a display device of an embodiment of the present invention;

FIG. 15A and FIG. 15B are cross-sectional schematic diagrams for explaining a manufacturing method of a display device of an embodiment of the present invention;

FIG. 16A and FIG. 16B are cross-sectional schematic diagrams for explaining a manufacturing method of a display device of an embodiment of the present invention; and

FIG. 17 is a cross-sectional schematic diagram for explaining a manufacturing method of a display device of an embodiment of the present invention.

### DESCRIPTION OF EMBODIMENTS

Each embodiment of the present invention is explained below while referring to the drawings. However, the present invention can be carried out in various modes without departing from the concept thereof, and is not to be interpreted as being limited to the description contents of the embodiments exemplified below.

Although the drawings may be schematically represented with the width, thickness, shape and the like of each part as compared with the actual form in order to clarify the explanation more clearly, they are only an example and does not limit an interpretation of the present invention. Elements having the same functions as those described with reference to the preceding figures in the present specification and each figure are attached with the same reference numerals and overlapping explanations may be omitted.

In the present invention, when a single film is processed to form a plurality of films, these films may have different functions and roles. However, the plurality of films are derived from films formed in the same layer by the same process and have the same layer structure and the same material. Therefore, these films are defined as existing in the same layer.

In one embodiment of the present invention, when expressing a mode in which another structure is arranged above a certain structure, in the case where it is simply described as [above], unless otherwise noted, a case where another structure is arranged directly above a certain structure as if in contact with that structure, and a case where another structure is arranged via another structure above a certain structure, are both included.

### First Embodiment

### 1-1. Overall Structure

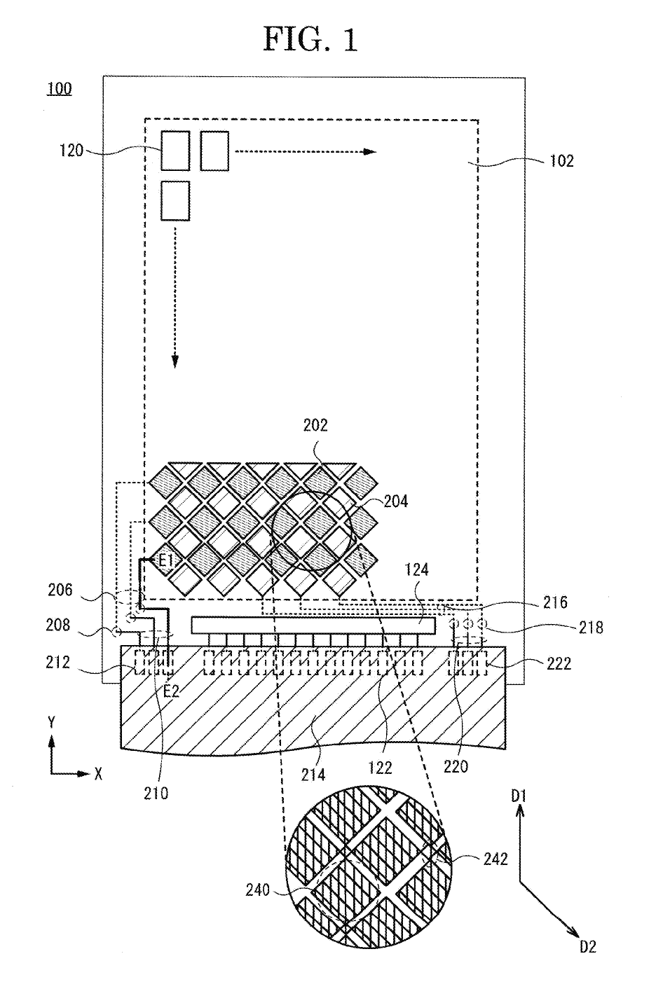

FIG. 1 is a schematic plan view of a display device 100 mounted with a touch sensor (hereinafter referred to simply as display device) according to a first embodiment of the present invention. The display device 100 has a display region 102 for displaying images. A plurality of first touch electrodes 202 extending in a X direction and arranged in a Y direction which intersects the X direction, and a plurality of second touch electrodes 204 extending in the Y direction and arranged in the X direction are arranged to overlap above the display region 102. Each first touch electrode 202 and each second touch electrode 204 may be arranged in different layers or may be mutually arranged in the same layer and only the parts where they intersect each other may be made to intersect using different layers so as not to short circuit. A so-called projected-capacitive electrostatic capacitance type touch sensor 200 is formed by a plurality of the first touch electrodes 202 and a plurality of the second touch electrodes 204. The projected-capacitive electrostatic capacitance type is largely divided into a self-capacitance type and a mutual capacitance type.

In the self-capacitance type, when a detection object such as a human finger touches or approaches (hereinafter touching and approaching are both referred to as a touch) the display area 102 via the first touch electrode 202 and second touch electrode 204, a capacitance formed by the first touch electrode 202 or the second touch electrode 204 and the detection object changes, and the position of the touch is determined by reading this change.

In the mutual capacitance type, one of the first touch electrode 202 and the second touch electrode 204 is called a transmission electrode (Tx) and the other is called a reception electrode (Rx). When a detection object such as a human finger touches the display region 102 via the first touch electrode 202 and the second touch electrode 204, the capacitance formed by the first touch electrode 202 and the second touch electrode 204 changes, and the position of the touch is determined by reading this change.

The display device 100 of the present embodiment can be applied to either the self-capacitance type or the mutual capacitance type.

As is shown in an enlarged view of a region of part of the touch sensor 200 inserted in FIG. 1, each of the first touch electrode 202 and the second touch electrode 204 has a plurality of quadrangular regions (diamond electrode) 240 which have an almost square shape, and a plurality of connection regions 242, and these mutually alternate with each other. The first touch electrode 202 and the second touch electrode 204 are mutually separated from each other and are electrically independent.

The first touch electrode 202 is electrically connected to a first wiring 206 which extends from outside of the display region 102. The first wiring 206 extends outside the display region 102 and is electrically connected to a first terminal wiring 210 in a contact hole 208. The first terminal wiring 210 is exposed in the vicinity of an end part of the display device 100 to form a first terminal 212. The first terminal 212 is connected to a flexible print (FPC) substrate 214, and a touch sensor signal is inputted from an external circuit (not shown in the diagram) to the first touch electrode 202 via the first terminal 212.

Similarly, the second touch electrode 204 is electrically connected to a second wiring 216 which extends from the outside of the display region 102. The second wiring 216 extends outside the display region 102 and is electrically connected to a second terminal wiring 220 in a contact hole 218. The second terminal wiring 220 is exposed in the vicinity of an end part of the display device 100 to form a second terminal 222. The second terminal 222 is connected to a connector 214, and a touch sensor signal is inputted from an external circuit to the second touch electrode 204 via the second terminal 222.

FIG. 1 further shows a third terminal 122 for applying a signal to a pixel 120 in the display region 102 and an IC chip 124 for controlling driving of the pixel 120. As is shown in FIG. 1, the first terminal 212, the second terminal 222, and the third terminal 122 can be formed so as to be aligned on one side of the display device 100, and as a result, it is possible to apply a signal to the display area 102 and the touch sensor 200 using the flexible printed substrate 214.

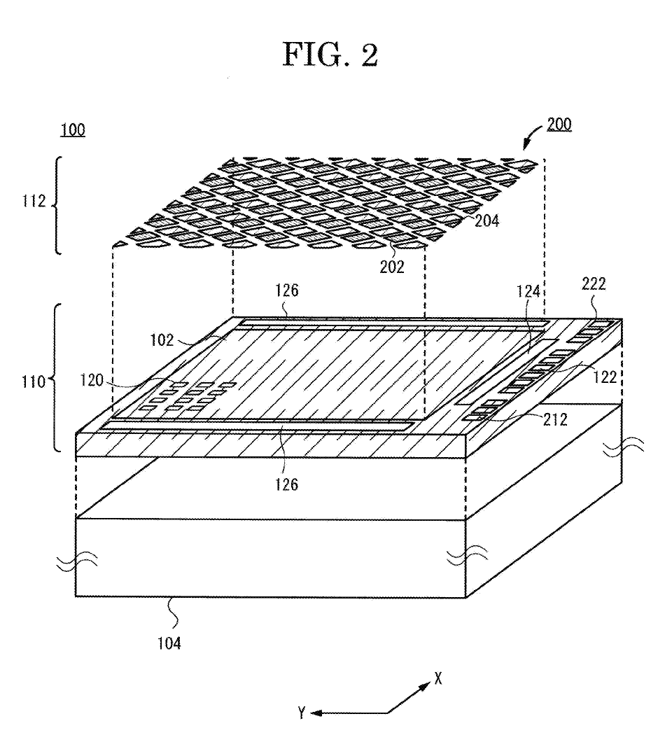

FIG. 2 shows a schematic perspective view of the display device 100. Here, in order to promote understanding, the substrate 104, a first layer 110 including the display region 102, and a second layer 112 including the touch sensor 200 are shown separately from each other.

The substrate 104 has flexibility and also a bending axis defined in a Y direction. The direction along this bending axis is defined as a first direction D1. Here, the bending axis of the substrate 104 means a direction in which a curvature radius does not change before and after bending when the planar shaped substrate 104 is folded. Here, the first direction D1 may be defined in consideration of the arrangement of a plurality of pixels 120 in the display region arranged above the substrate 104. As an example, when a plurality of pixels 120 are arranged in a matrix shape in two directions mutually intersecting each other, that is, in the X direction and the Y direction, it is sufficient that one of the two directions is defined as the first direction D1. As another example, the vertical direction or the horizontal direction in the display screen may be defined as the first direction D1.

The first layer 110 is arranged above the substrate 104. The first layer 110 includes the display region 102 described above, and the display region 102 has a plurality of pixels 120 arranged in a matrix shape. A scanning line drive circuit 126 for controlling driving of the pixel 120 is arranged on the outer side of the display region 102. The scanning line drive circuit 126 does need not be formed directly on the substrate 104, and a driving circuit formed on a substrate (a semiconductor substrate or the like) different from the substrate 104 may be arranged above the substrate 104 or the flexible printed substrate 214, and each pixel 120 may be controlled by these driving circuits. Although not shown in the diagram, various semiconductor elements for controlling a light emitting element arranged in a pixel 120 are formed in the first layer 110.

As described above, the touch sensor 200 is formed by a plurality of first touch electrodes 202 and a plurality of second touch electrodes 204. The touch sensor 200 may have substantially the same size and shape as the display region 102.

### 1-2. Pixel

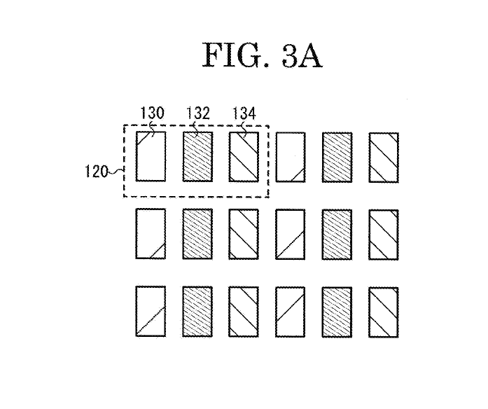

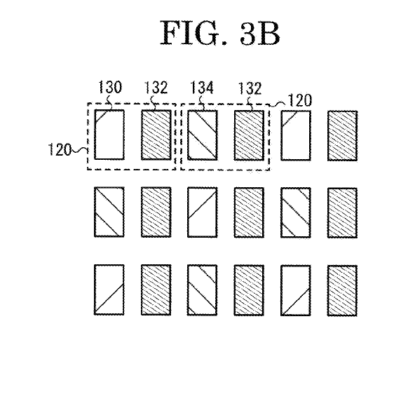

In the present embodiment, a pixel 120 has a plurality of subpixels, and for example, as is shown in FIG. 3A, the subpixels are arranged so that a first subpixel 130, a second subpixel 132, and a third subpixel 134 form one pixel 120. Each subpixel is arranged with one display element such as a light emitting element or a liquid crystal element. The color provided by a subpixel is determined by the characteristics of the light emitting element or a color filter arranged above the subpixel. In one embodiment of the present invention, a pixel 120 means a pixel having one display element and a plurality of subpixels providing at least one different color, and is the smallest unit forming a part of an image reproduced in the display region 102. The subpixels in the display region 102 are included in any of the pixels 120.

In the arrangement exemplified in FIG. 3A, the first subpixel 130, the second subpixel 132 and the third subpixel 134 may be formed to provide different colors, for example, it is possible to arrange each of the first subpixel 130, the second subpixel 132, and the third subpixel 134 with light emitting elements that emit the three primary colors of red, green and blue, respectively. In this way, it is possible to create arbitrary colors in each pixel 120.

In the arrangement shown in FIG. 3B, one of the pixel 120 includes two subpixels corresponding to different colors respectively. For example, the pixel 120 includes a first subpixel 130 and a second subpixel 132 which provide red and green, and an adjacent pixel 120 can include a third subpixel 134 and second subpixel 132 which provide blue and green. In this case, the reproduced color gamut will be different between adjacent pixels 120.

It is not necessary that the shape of the subpixels in each pixel 120 is the same. For example, as is shown in FIG. 3C, one subpixel may have a shape different from the other two subpixels. In this case, for example, the subpixel 134 which provides blue color may be formed with the largest area, and the second subpixel 132 and the first subpixel 130 which provide green and red colors may have the same size area.

### 1-3. Touch Electrode

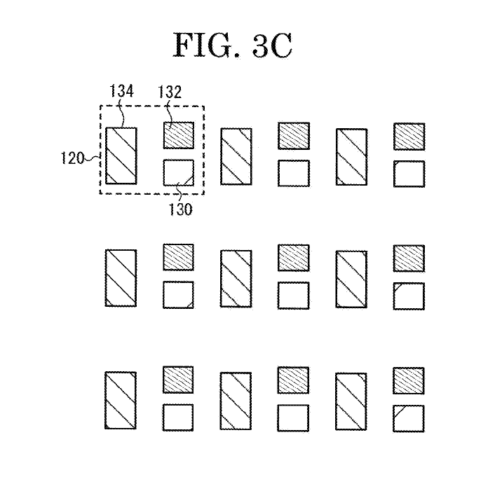

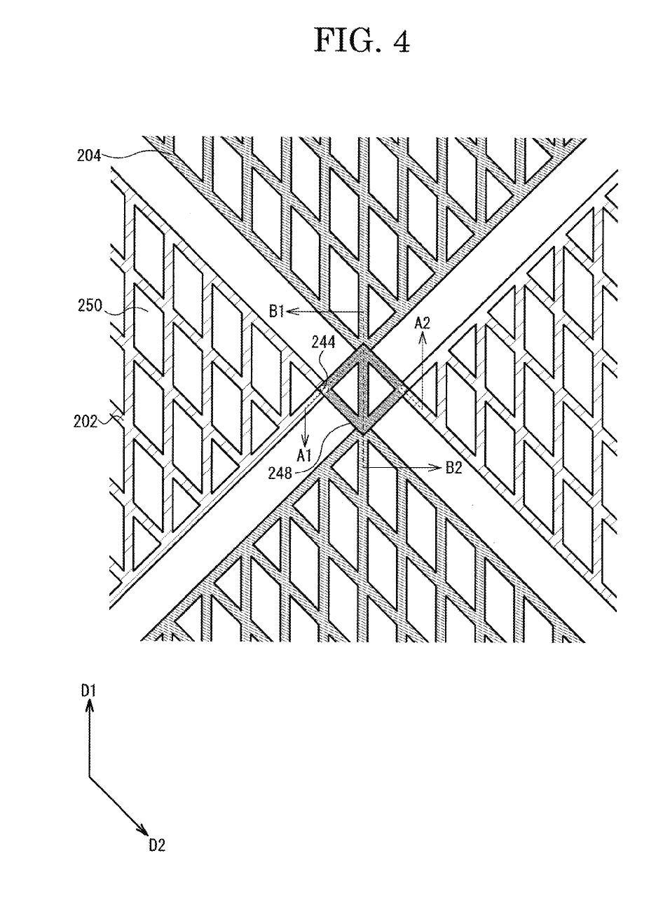

FIG. 4 schematically shows an enlarged plan view of the first touch electrode 202 and the second touch electrode 204. Both the first touch electrode 202 and the second touch electrode 204 have a mesh shape. That is, these electrodes are mesh shaped wirings and have a plurality of openings 250. The width of the wiring is 1 μm to 10 μm or 2 μm to 8 μm, and typically 5 μm.

More specifically, each of the plurality of touch electrodes has a mesh structure formed including a conducting part which extends in a first direction D1 and a conducting part which extends in a second direction D2. The conducting part is arranged on the outer side of a light emitting element of each of the plurality of subpixels in a plan view. Here, the second direction D2 intersects with first direction D1 and also intersects the direction orthogonal to the first direction D1. That is, an angle formed by the first direction D1 and the second direction D2 is not a right angle. In other words, the angle formed by the first direction D1 and the second direction D2 is less than 90 degrees.

By adopting such a structure, cracks and disconnections and the like are less likely to occur in a plurality of touch electrodes having a mesh structure due to bending of the display device 100 having a bending axis in the first direction D1. When the display device 100 is bent with the first direction D1 as a bending axis, the direction on the substrate 104 where a change in curvature is largest before and after the bending is a direction orthogonal to the first direction.

In the present embodiment, the angle formed by the first direction D1 and the second direction D2 is not a right angle. Therefore, compared with the case where the angle formed by the first direction D1 and the second direction D2 is a right angle with respect to bending of the display device 100 with the first direction D1 as the bending axis, it is possible to reduce the amount of change in the curvature of the conducting part extending in the second direction. As a result, cracks and disconnections and the like of the conducting part extending in the second direction hardly occur.

The angle on the acute angle side formed by the first direction D1 and the second direction D2 is preferably 20 degrees or more and 60 degrees or less. If the angle is larger than this range, the effect of suppressing cracks and disconnections and the like of the conducting part extending in the second direction D2 is reduced. On the other hand, if the angle is smaller than this range, the layout design of the mesh wiring becomes difficult.

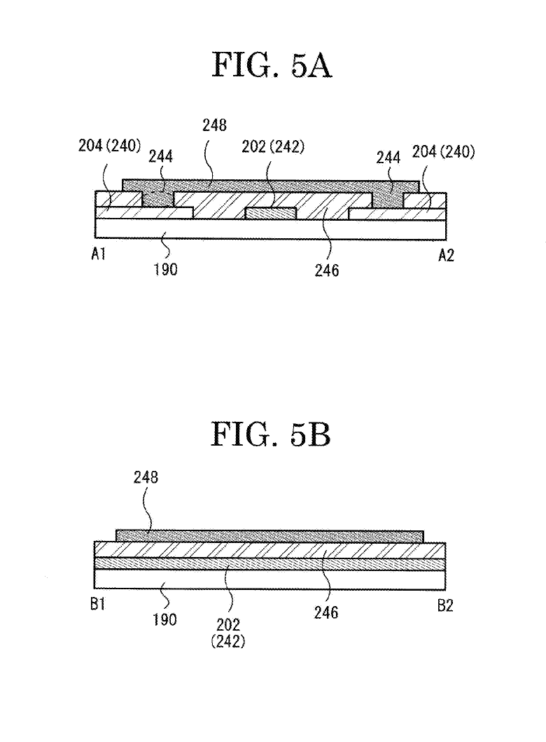

FIG. 5A and FIG. 5B show cross-sections along one dotted line A1-A2 and one dotted line B1-B2 in FIG. 4, respectively. As is shown in FIG. 5A and FIG. 5B, the first touch electrode 202 and the second touch electrode 204 are arranged above an insulating film 190 (described herein) with both a diamond electrode 240 and a connection region 242. The first touch electrode 202 and the second touch electrode 204 may be in contact with the insulating film 190. Here, the first touch electrode 202 and the second touch electrode 204 may exist in the same layer. More specifically, the diamond electrode 240 of the first touch electrode 202 and the second touch electrode 204 may mutually exist in the same layer. By arranging the first touch electrode 202 and the second touch electrode 204 in the same layer, optical characteristics such as reflection characteristics of both the first touch electrode 202 and the second touch electrode 204 become substantially the same. As a result, it is difficult to visually recognize the first touch electrode 202 and the second touch electrode 204, that is, they can be made inconspicuous.

An interlayer insulating film 246 is arranged above the first touch electrode 202, and a bridge wiring 248 is formed above the interlayer insulating film 246. The bridge wiring 248 is electrically connected to two adjacent diamond electrodes 240 of the second touch electrode 204 in an opening 244 arranged in the interlayer insulating film 246. Therefore, the bridge wiring 248 can also be recognized as a connection region 242 of the second touch electrode 204. The interlayer insulating film 246 electrically insulates the first touch electrode 202 and the second touch electrode 204 from each other and also functions as a dielectric forming a capacitance between the first touch electrode 202 and the second touch electrode 204.

Although an example of a second touch electrode 204 formed above the first touch electrode 202 and a bridge wiring 248 electrically connected to the diamond electrode 240 of the second touch electrode 204 is shown in FIG. 4, FIG. 5A, and FIG. 5B. As another aspect, a structure is also possible in which the first touch electrode 202 is formed above the second touch electrode 204 and the bridge wiring 248 is electrically connect the diamond electrode 240 of the first touch electrode 202. With respect to the vertical relationship between a touch electrode and a bridge wiring, either one may be the upper layer.

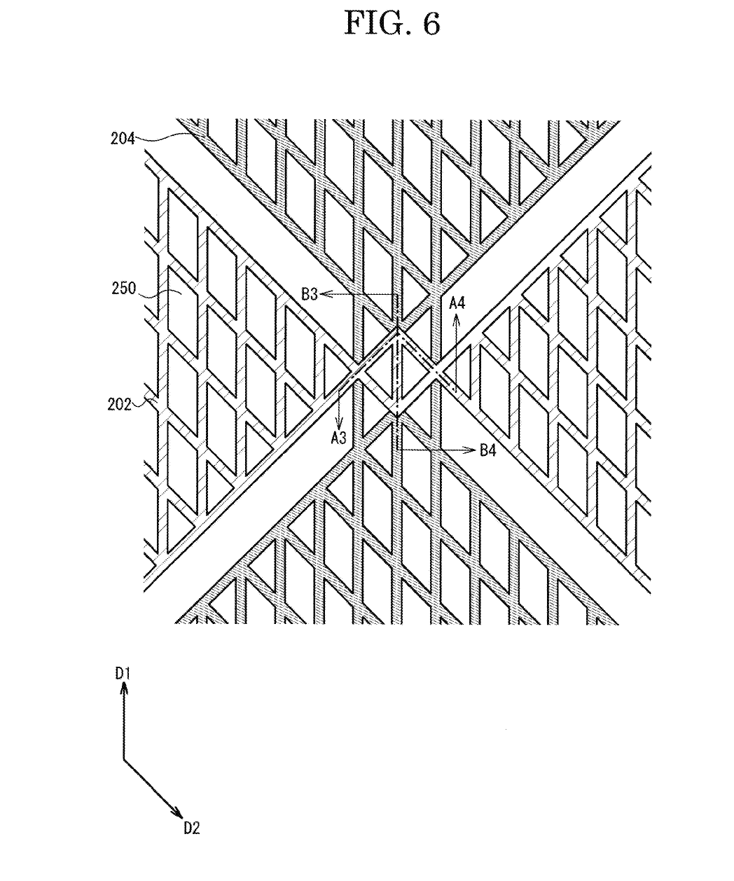

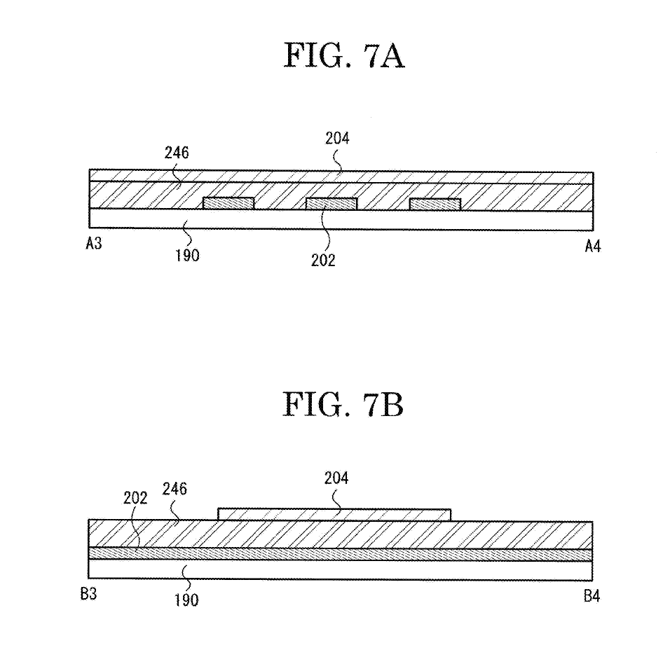

Furthermore, as is shown in FIG. 6, FIG. 7A, and FIG. 7B which are schematic cross-sectional views along the dotted line A3-A4, and the dotted line B3-B4 in FIG. 6, the first touch electrode 202 and the second touch electrode 204 may exist in different layers. More specifically, the diamond electrode 240 of the first touch electrode 202 and the second touch electrode 204 and the connection region 242 may mutually exist in different layers. In this case, the interlayer insulating film 246 is arranged between the first touch electrode 202 and the second touch electrode 204. When such a structure is adopted, since it is not necessary to form the opening 244, the process is simplified, and it is possible to contribute to an improvement in yield.

Although described in the second embodiment, the first touch electrode 202 and the second touch electrode 204 may also include a metal with light shielding properties (zero valent metal). This is because since the wiring having a mesh structure of the first touch electrode 202 and the second touch electrode 204 is arranged on the outer side of a light emitting element, it is not necessary to use a conventionally used conductive oxide having translucency. Examples of the light shielding metal include molybdenum, titanium, chromium, tantalum, copper, aluminum and tungsten and the like. By forming the first touch electrode 202 and the second touch electrode 204 so as to include a zero-valent metal as a main component, cracks and disconnections and the like hardly occur compared with conventionally used conductive oxides having translucency. Furthermore, because these electrical resistances can be greatly reduced, it is possible to reduce the time constant of a response. As a result, the response speed of the sensor can be improved.

### 1-4. Cross-Sectional Structure

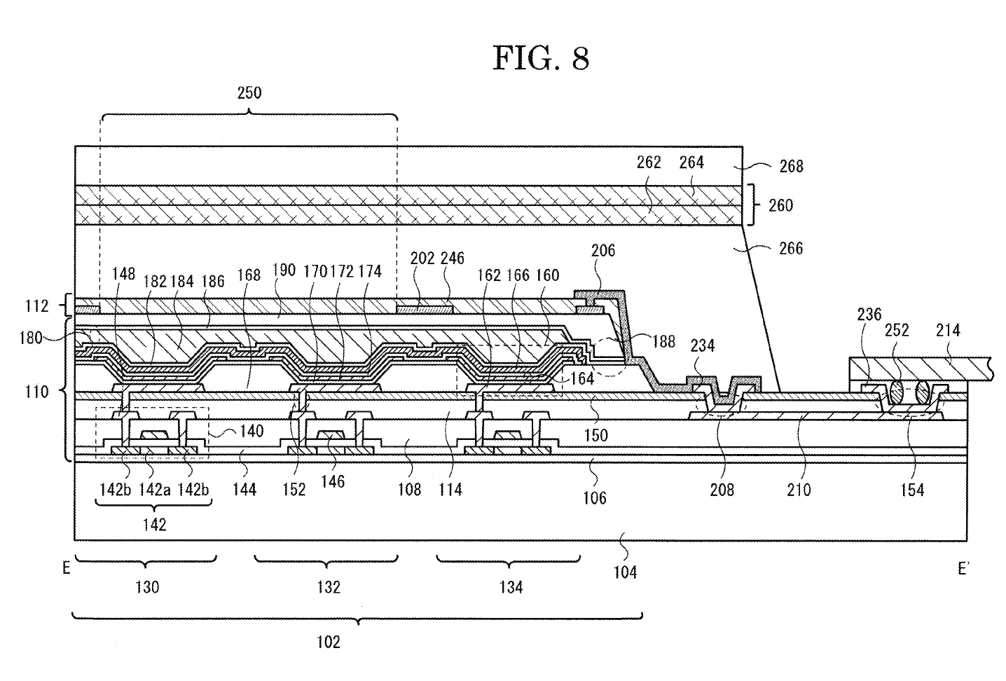

FIG. 8 is a schematic cross-sectional view of the display device 100. FIG. 8 is a cross-section along the dotted line E1-E2 in FIG. 1 and schematically shows a cross-section from the display region 102 to the first wiring 206, the first terminal wiring 210 and the first terminal 212.

The display device 100 includes a first layer 110 and a second layer 112 above a substrate 104. In the case where the substrate 104 has plasticity, the substrate 104 may be referred to as a base member, a base film, or a sheet substrate. As is described herein, the first layer 110 is arranged with a transistor and a light emitting element for controlling the first subpixel 130, the second subpixel 132, and the third subpixel 134 and contributes to image reproduction. On the other hand, the second layer 112 is arranged with a touch sensor 200 which contributes to touch detection.

### 1-4-1 First Layer

A transistor 140 is arranged via an underlying film 106 having an arbitrary structure above the substrate 104. The transistor 140 includes a semiconductor film 142, a gate insulating film 144, a gate electrode 146 and a source/drain electrode 148 and the like. The gate electrode 146 overlaps with the semiconductor film 142 with the gate insulating film 144 interposed therebetween, and a region overlapping with the gate electrode 146 is a channel region 142a of the semiconductor film 142. The semiconductor film 142 may include a source/drain region 142b so as to sandwich the channel region 142a therebetween. It is possible to arrange an interlayer film 108 above the gate electrode 146, and the source/drain electrode 148 is connected to the source/drain region 142b in an opening arranged in the interlayer film 108 and the gate insulating film 144.

A first terminal wiring 210 is arranged above the interlayer film 108. As is shown in FIG. 8, the first terminal wiring 210 may exist in the same layer as the source/drain electrode 148. Although not shown in the diagram, the first terminal wiring 210 may be formed to exist in the same layer as the gate electrode 146.

Although the transistor 140 is shown as a top gate type transistor in FIG. 8, the structure of the transistor 140 is not limited. The structure of the transistor is a bottom gate type transistor, a multi-gate type transistor having a plurality of gate electrodes 146, or a dual gate type transistor having a structure in which it is sandwiched by two gate electrodes 146 may also be used. Although FIG. 8 shows an example in which one transistor 140 is arranged for each of the first subpixel 130, the second subpixel 132, and the third subpixel 134, the first subpixel 130, the second subpixel 132 and the third subpixel 134 may further include a semiconductor element such as a plurality of transistors and a capacitor element.

A planarization film 114 is arranged above the transistor 140. The planarization film 114 has a function of absorbing irregularities caused by the transistor 140 and other semiconductor elements and for providing a flat surface.

An inorganic insulating film 150 may be formed above the planarization film 114. The inorganic insulating film 150 has a function of protecting a semiconductor element such as the transistor 140. The inorganic insulating film 150 is provided between a first electrode 162 of the light emitting element 160 described later and an electrode (not shown in the diagram) formed under the inorganic insulating film 150 and is provided to form a capacitor.

The planarization film 114 and the inorganic insulating film 150 are arranged with a plurality of openings. One of the openings is a contact hole 152 and is used for electrical connection between the first electrode 162 of the light emitting element 160 described herein and the source/drain electrode 148. One of the openings is a contact hole 208 which is used for electrical connection between the first wiring 206 and the first terminal wiring 210. Another opening is an opening 154 and is arranged to expose a part of the first terminal wiring 210. The first terminal wiring 210 exposed at the opening 154 is connected to the flexible printed circuit board 214 by, for example, an anisotropic conductive film 252 or the like.

The light emitting element 160 is formed above the planarization film 114 and the inorganic insulating film 150. The light emitting element 160 includes a first electrode (pixel electrode) 162, a functional layer 164, and a second electrode (opposing electrode) 166. More specifically, the first electrode 162 covers the contact hole 152 and is arranged to be electrically connected to the source/drain electrode 148. In this way, a current is supplied to the light emitting element 160 through the transistor 140. A partition wall 168 is arranged to cover an end part of the first electrode 162. By covering an end part of the first electrode 162 with the partition wall 168, it is possible to prevent break of the functional layer 164 and the second electrode 166 arranged above. The functional layer 164 is arranged to cover the first electrode 162 and the partition wall 168, and the second electrode 166 is formed thereupon. Carriers are injected into the functional layer 164 from the first electrode 162 and the second electrode 166, and carrier recombination occurs in the functional layer 164. In this way, light emitting molecules within the functional layer 164 are brought to an excited state, and light emission is obtained through a process of relaxation to a ground state. Therefore, a region where the first electrode 162 and the functional layer 164 are in contact serves as a light emitting region in the first subpixel 130, the second subpixel 132 and the third subpixel 134.

The structure of the functional layer 164 can be appropriately selected and can be formed by combining, for example, a carrier injection layer, a carrier transport layer, a light emitting layer, a carrier blocking layer, an exciton blocking layer and the like. FIG. 8 shows an example in which the functional layer 164 has a first functional layer 170, a second functional layer 172 and a third functional layer 174. In this case, for example, the first functional layer 170 can be a carrier (hole) injection or transport layer, the second functional layer 172 can be a light emitting layer, and the third functional layer 174 can be a carrier (electron) injection or transport layer. As is shown in FIG. 8, the second functional layer 172 which is a light emitting layer can be formed to include different materials for the first subpixel 130, the second subpixel 132 and the third subpixel 134. In this case, the first functional layer 170 and the third functional layer 174 are formed so as to be shared by the first subpixel 130, the second subpixel 132 and the third subpixel 134 and formed across the top of the first subpixel 130, the second subpixel 132, the third subpixel 134 and the partition wall 168. By appropriately selecting the material used in the second functional layer 172, different light emission colors can be obtained in the first subpixel 130, the second subpixel 132 and the third subpixel 134. Alternatively, the structure of the third functional layer 174 may be the same between the first subpixel 130, the second subpixel 132 and the third subpixel 134. In this case, the third functional layer 174 is also shared between the first subpixel 130, the second subpixel 132 and the third subpixel 134, and is formed across the top of the first subpixel 130, the second subpixel 132 and the third subpixel 134 and the partition wall 168. In such a structure, since the same light emission color is output from the second functional layer 172 of the first subpixel 130, the second subpixel 132 and the third subpixel 134, for example, the second functional layer 172 can have a structure which can emit white light, and various colors (for example, red, green and blue) can be extracted from the first subpixel 130, the second subpixel 132 and the third subpixel 134, respectively, by using a color filter.

Furthermore, the display device 100 may further include connection electrodes 234 and 236 which cover the contact hole 208 and the opening 154 and are in contact with the first terminal wiring 210. These connection electrodes 234, 236 can exist in the same layer as the first electrode 162. By forming the connection electrodes 234 and 236, it is possible to reduce damage to the first terminal wiring 210 in the manufacturing process of the display device 100, and electrical connection with low contact resistance can be realized.

A sealing film (passivation film) 180 is arranged above the light emitting element 160. The sealing film 180 has a function of preventing impurities (water, oxygen and the like) from entering the light emitting element 160 and the transistor 140 from the exterior. As is shown in FIG. 8, the sealing film 180 may include three layers. For example, in the sealing film 180, an inorganic insulating film including an inorganic compound can be used for the first inorganic film 182 and the second inorganic film 186. On the other hand, it is possible to use an organic film 184 including an organic compound between the first inorganic film 182 and the second inorganic film 186. It is possible to form the organic film 184 so as to absorb irregularities caused by the light emitting element 160 and the partition wall 168 and provide a flat surface. As a result, the thickness of the organic film 184 can be set relatively large. As a result, it is possible to increase the distance between the first touch electrode 202 and the second touch electrode 204 of the touch sensor 200 and one electrode (second electrode 166) of a light emitting element 160 described herein. As a result, it is possible to significantly reduce parasitic capacitance which is generated between the touch sensor 200 and the second electrode 166.

Furthermore, it is preferred that the first inorganic film 182 and the second inorganic film 186 are formed so as to stay within the display region 102. In other words, the first inorganic film 182 and the second inorganic film 186 are provided so as not to overlap the contact hole 208 and the opening 154. In this way, electrical connection with low contact resistance between the first terminal wiring 210 and the flexible printed circuit substrate 214 and the first wiring 206 becomes possible. Furthermore, it is preferred that the first inorganic film 182 and the second inorganic film 186 are in direct contact with each other at the end of the display region 102 (see the region surrounded by a circle 188 in FIG. 8). In this way, since it is possible to seal the organic film 184 having high hydrophilicity using the first inorganic film 182 and the second inorganic film 186 as compared with the first inorganic film 182 and the second inorganic film 186, it is possible to more effectively prevent impurities from entering from the exterior and prevent the diffusion of impurities into the display region 102.

The display device 100 further includes an insulating film 190 that covers the display region 102 above the sealing film 180. It is possible to arrange the insulating film 190 to be in contact with the second inorganic film 186 of the sealing film 180. An organic insulating film can be used as the material of the insulating film 190.

The first layer 110 is formed by the various elements and films described above.

### 1-4-2 Second Layer

The second layer 112 includes a first touch electrode 202, a second touch electrode 204, an interlayer insulating film 246, a bridge wiring 248, a first wiring 206 and a second wiring 216 and the like.

The first touch electrode 202 is a mesh shaped wiring including an opening 250. This wiring may be arranged above the sealing film 180 and the insulating film 190 so as to overlap the partition wall 168 and to extend along the partition wall 168 (described herein). The first touch electrode 202 or the second touch electrode 204 may be in direct contact with the insulating film 190.

The interlayer insulating film 246 is in contact with the first touch electrode 202 and is formed to cover the first touch electrode 202. An opening is formed in the interlayer insulating film 246, and the first wiring 206 is arranged to cover the opening. The first wiring 206 passes outside the display region 102 and extends to the contact hole 208 (see FIG. 1). The first wiring 206 is further electrically connected to the first terminal wiring 210 existing in the same layer as the source/drain electrode 148 (or the gate electrode 146) of the transistor 140 via the connection electrode 234 in the contact hole 208. In this way, the first touch electrode 202 and the first terminal wire 210 are electrically connected.

In the case where the first touch electrode 202 and the second touch electrode 204 are formed in the same layer, the diamond electrode 240 in either one of the touch electrodes can be connected by the bridge wiring 248 (see FIG. 4, FIG. 5A and FIG. 5B). In this case, the first wiring 206 can exist in the same layer as the bridge wiring 248. Therefore, the first wiring 206 and the bridge wiring 248 can be formed at the same time.

On the other hand, in the case where the first touch electrode 202 and the second touch electrode 204 are formed to exist in different layers (see FIG. 6), the first wiring 206 can exist in the same layer and be formed at the same time of the first touch electrode 202 and the second touch electrode 204 whichever is positioned on the upper side.

### 1-4-3 Other Structures

As an arbitrary structure, the display device 100 may further include a circularly polarizing plate 260 overlapping with the display region 102. The circularly polarizing plate 260 can include a stacked layer structure of, for example, a ¼λ plate 262 and a linearly polarizing plate 264 arranged thereupon. When light incident from the exterior of the display device 100 passes through the linearly polarizing plate 264 to become linearly polarized light and then passes through the ¼λ plate 262, it becomes clockwise circularly polarized light. When this circularly polarized light is reflected by the first electrode 162 or the first touch electrode 202 and the second touch electrode 204, the circularly polarized light becomes counterclockwise circularly polarized light, and this again passes through the ¼λ plate 262 to become linearly polarized light. The polarization surface of the linearly polarized light at this time is orthogonal to the linearly polarized light before reflection. Therefore, the light cannot pass through the linearly polarizing plate 264. As a result, by arranging the circularly polarizing plate 260, it is possible to suppress reflection of external light and it is possible to provide an image with high contrast.

An organic protective film 266 may be arranged as a protective film between the circularly polarizing plate 260 and the second layer 112. The organic protective film 266 has a function of physically protecting the display device 100 and at the same time bonding the circular polarizing plate 260 and the second layer 112. As a further optional structure, a cover film 268 may be arranged above the display device 100. The cover film 268 has a function of physically protecting the circularly polarizing plate 260.

### 1-5. Layout of Touch Electrode and Pixel

As described above, each of the first touch electrode 202 and the second touch electrode 204 of the present embodiment is a mesh wire. In other words, each has openings 250 arranged in a matrix shape. As is shown in the cross-sectional view of FIG. 8, the wirings of the first touch electrode 202 and the second touch electrode 204 may overlap with the partition wall 168.

Here, the first subpixel 130, the second subpixel 132 and the third subpixel 134 are a first subpixel, a second subpixel, and a third subpixel, respectively, and the colors corresponding to each subpixel are a first color, a second color and a third color, and the first color, the second color and the third color are mutually different from each other.

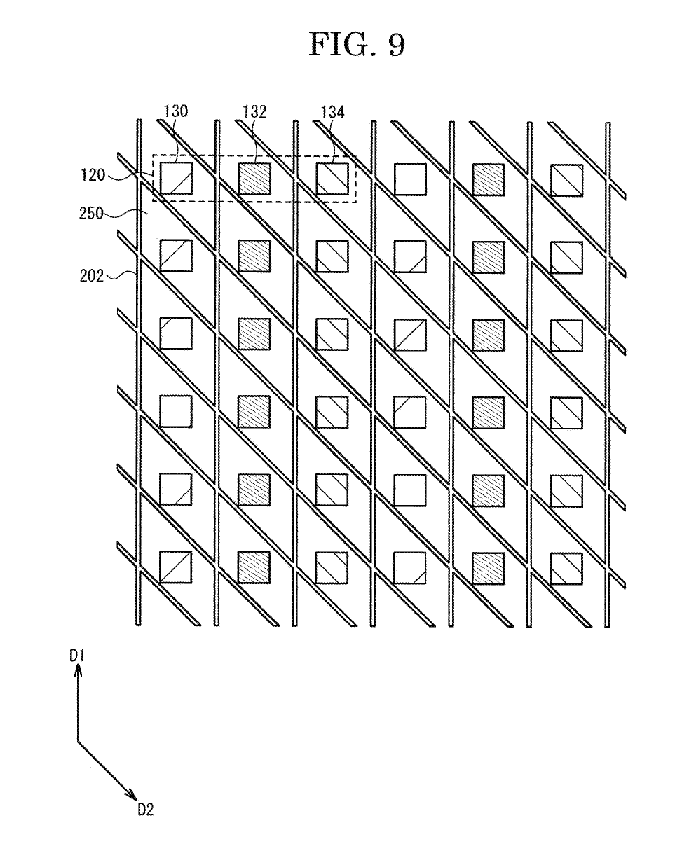

FIG. 9 is a plan view diagram showing an example of a layout of a touch electrode and a pixel in the display device 100 according to the present embodiment. The plurality of pixels 120 are arranged in a matrix shape in the first direction D1 and a direction intersecting the first direction D1. In this example, the plurality of pixels 120 are arranged in a matrix in the first direction D1 and a direction orthogonal to the first direction D1. That is, one direction is parallel to the first direction D1 in the plurality of pixels 120 arranged in a matrix shape in mutually intersecting directions. In addition, in this example, the first subpixel 130, the second subpixel 132 and the third subpixel 134 all have the same shape and size. Furthermore, these subpixels are arranged in a row and column shape in the first direction D1 and a direction orthogonal to the first direction D1. The touch electrode includes a conducting part extending in the first direction and a conducting part extending in the second direction. In this example, the acute angle side angle formed by the first direction and the second direction is approximately 45 degrees. One subpixel is arranged in a region in each of the plurality of openings of the touch electrode.

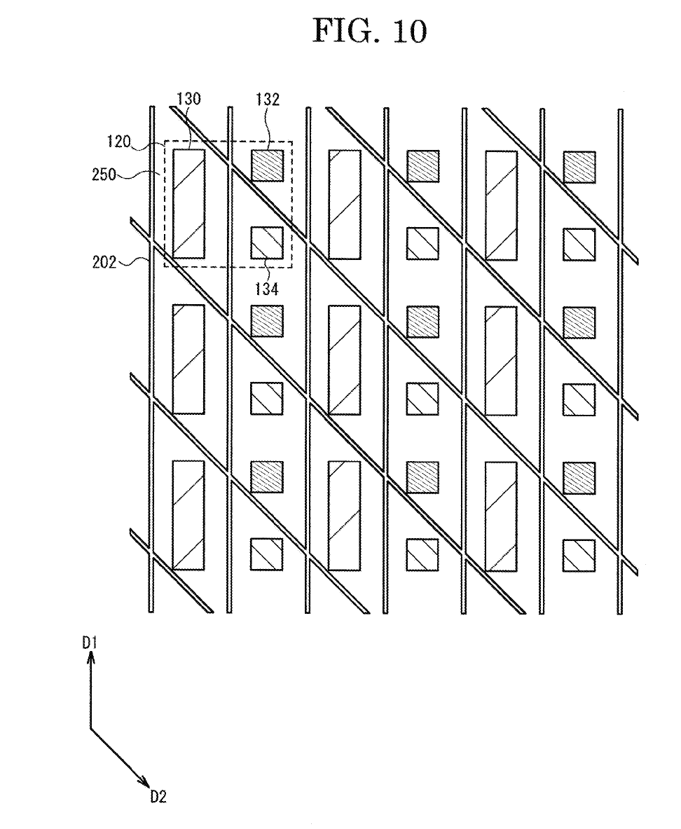

FIG. 10 is a plan view diagram showing another example of the layout of a touch electrode and a pixel in the display device 100. In this example, the second subpixel 132 and the third subpixel 134 have the same shape and size. Furthermore, these subpixels are arranged in the first direction D1 and a direction orthogonal to the first direction D1. The touch electrode has a conducting part extending in the first direction and a conducting part extending in the second direction. In this example, the acute angle side angle formed by the first direction and the second direction is approximately 45 degrees. One of the first subpixel 130 or two of the second subpixel 132 and the third subpixel 134 are arranged in each region of the plurality of openings of the touch electrode. As in this example, in the display device 100, at least two of the first subpixel 130, the second subpixel 132 and the third subpixel 134 may have light emitting regions with mutually different shapes or sizes.

By having such a structure, it is possible to minimize an interval between wirings having a mesh structure. That is, the area of the touch electrode can be made as large as possible. Specifically, another example of the mesh wiring in such a pixel layout is that it is possible to increase the area of a touch electrode in the example in FIG. 10 in the case of comparison with the case of a mesh structure having the conducting part extending in the first direction and a conducting part extending in a direction orthogonal to the first direction or a mesh structure having a conducting part extending in the second direction and a conducting part extending in a direction orthogonal to the second direction. In this way, it is possible to significantly increase a capacitance between a detection object and a touch electrode, and significantly increase a signal detected when the detection object touches a touch panel. In this way, it is possible to improve the sensitivity of a touch panel.

In the touch sensor 200 mounted on the display device 100 according to the present embodiment, it is possible to form the first touch electrode 202 and the second touch electrode 204 as a mesh shaped metal wiring having zero valent metal as a main component. As a result, cracks and disconnections and the like are less likely to occur compared with conventionally used conductive oxides having translucency. Furthermore, it is possible to reduce the electrical resistance of the first touch electrode 202 and the second touch electrode 204 and the time constant of a response. As a result, the response speed of a sensor can be improved. Although described in detail herein, the first touch electrode 202 and the second touch electrode 204 can be formed using photolithography. As a result, compared to a conventional method in which a touch panel is separately formed and mounted on a display device, it is possible to arrange the first touch electrode 202 and the second touch electrode 204 with high precision.

In addition, it is possible to arrange the display device 100 with a circularly polarizing plate 260. Therefore, external light reflected by the first touch electrode 202 and the second touch electrode 204 is not output to the exterior of the display device 100 and it is possible to prove a high-quality image with high contrast.

As described above, the first touch electrode 202 and the second touch electrode 204 have openings 250, and the wirings forming the openings 250 may be arranged along partitions between the light emitting elements 160. Therefore, each subpixel is located within an opening 250. Conventionally, since an electrode for a touch sensor is formed using a light transmitting conductive film such as ITO to overlap with a subpixel, the luminance of each pixel 120 is reduced due to the light absorption of the light transmitting conductive film. On the other hand, in the display device 100 of the present embodiment, the light emitted from a pixel 120 is not absorbed or shielded by a touch sensor. Therefore, it is possible to effectively utilize the light emission from the light emitting element 160 which can contribute to a reduction in power consumption.

In the display device 100, the signals provided to the first touch electrode 202 and the second touch electrode 204 are input via the first terminal wiring 210 and the second terminal wiring 220 which exist in the same layer as the source/drain electrode 148 of the transistor 140 for controlling the display region 102, or in the same layer as the gate electrode 146. As a result, it is possible to arrange provide terminals (first terminal 212, second terminal 222, third terminal 122) for inputting a signal to the touch sensor and inputting a signal to the display region 102 on the same substrate, and it is possible to reduce the number of terminals arranged on the flexible printed substrate 214.

### Second Embodiment

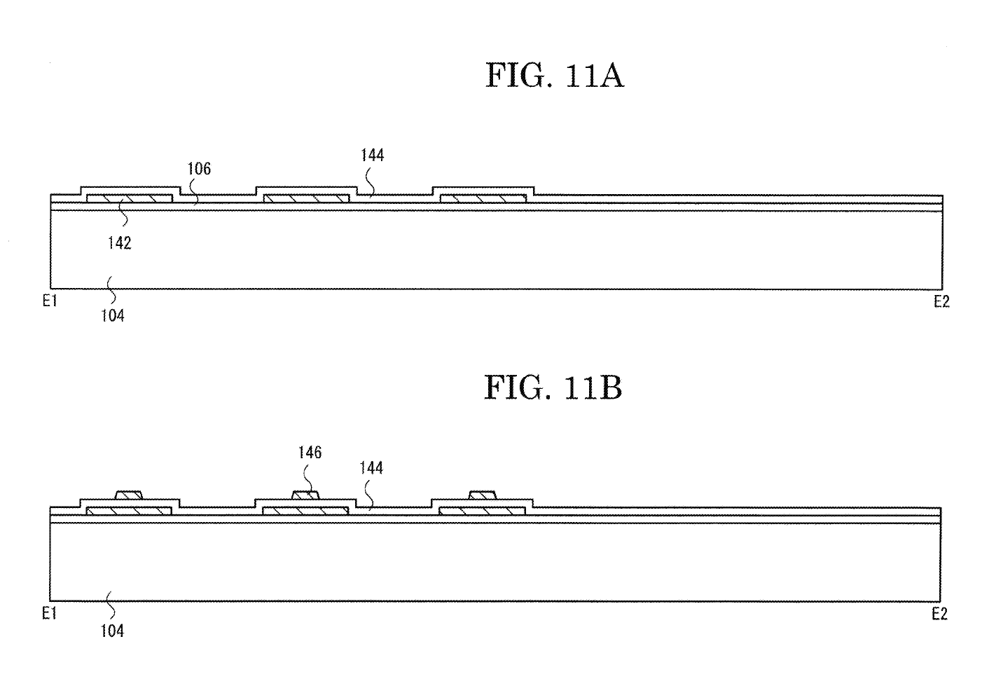

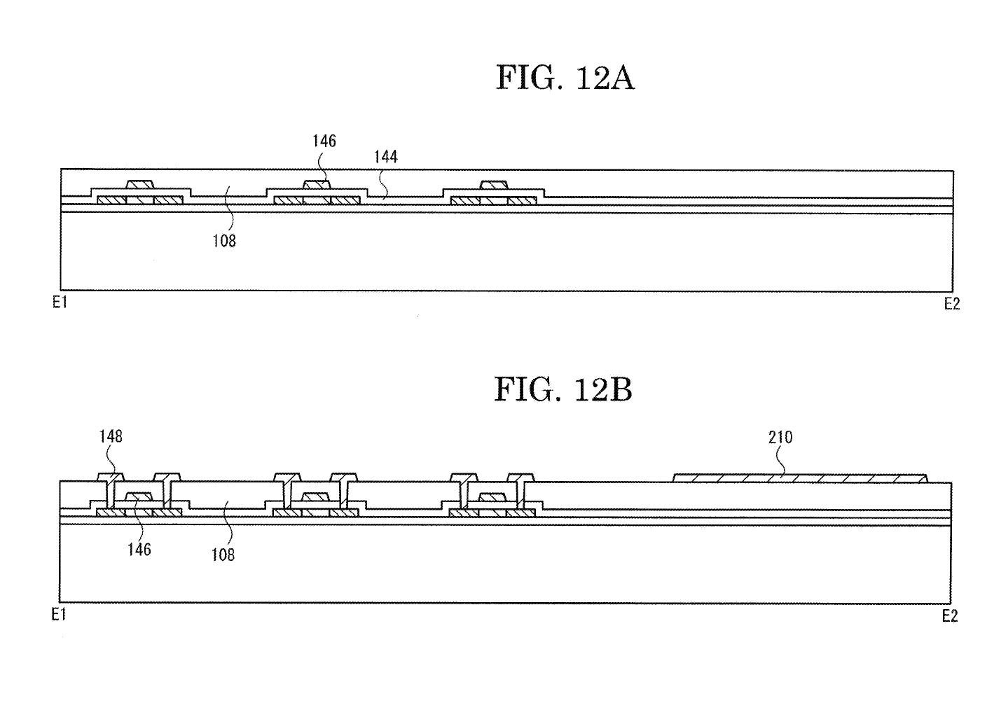

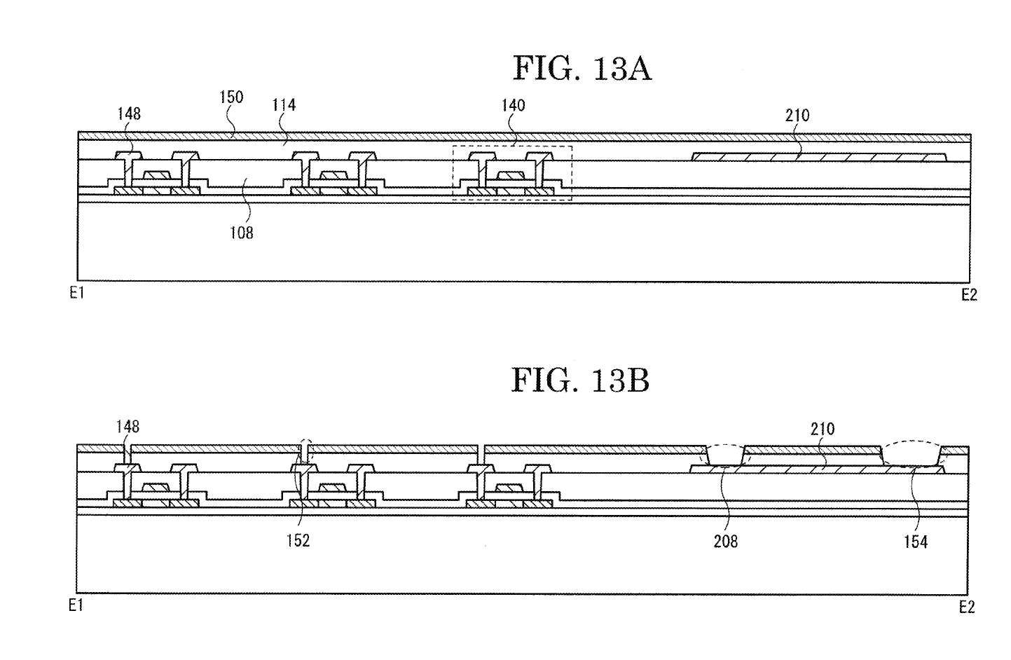

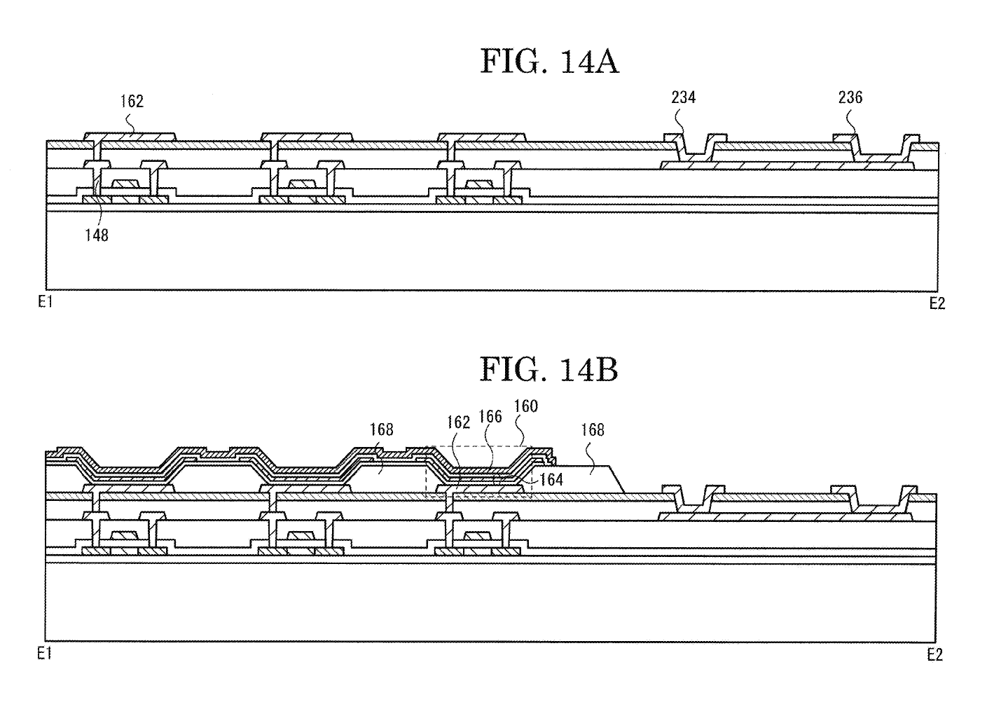

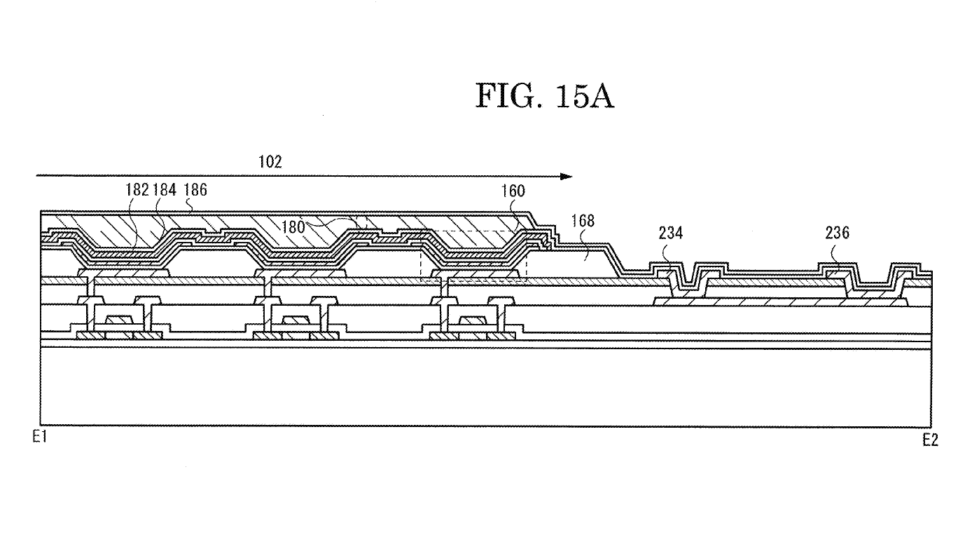

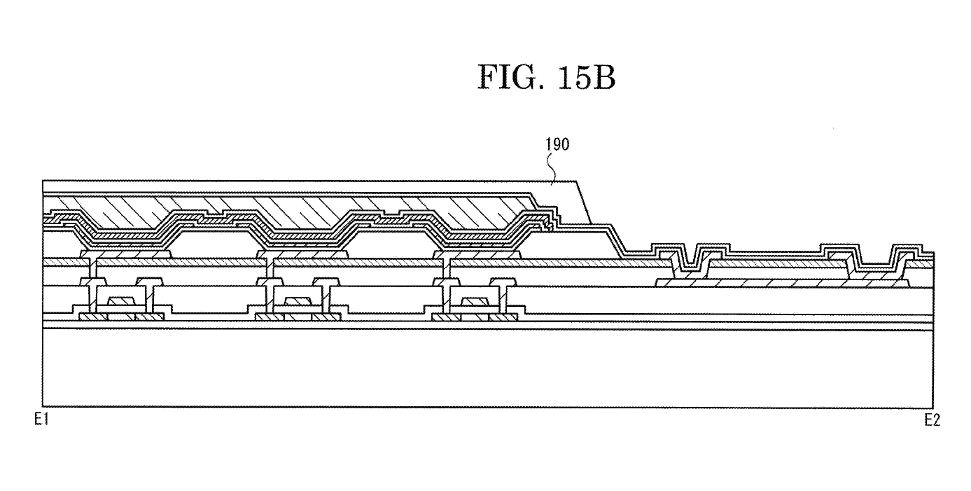

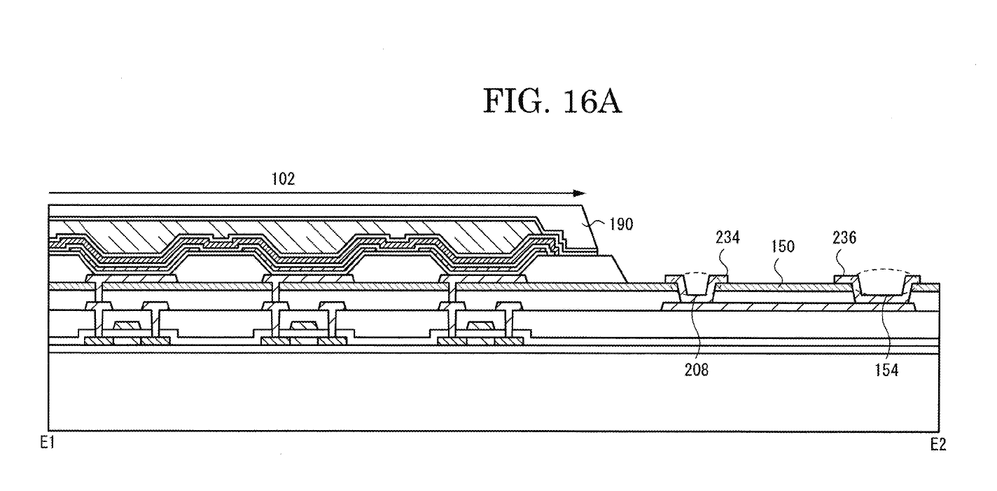

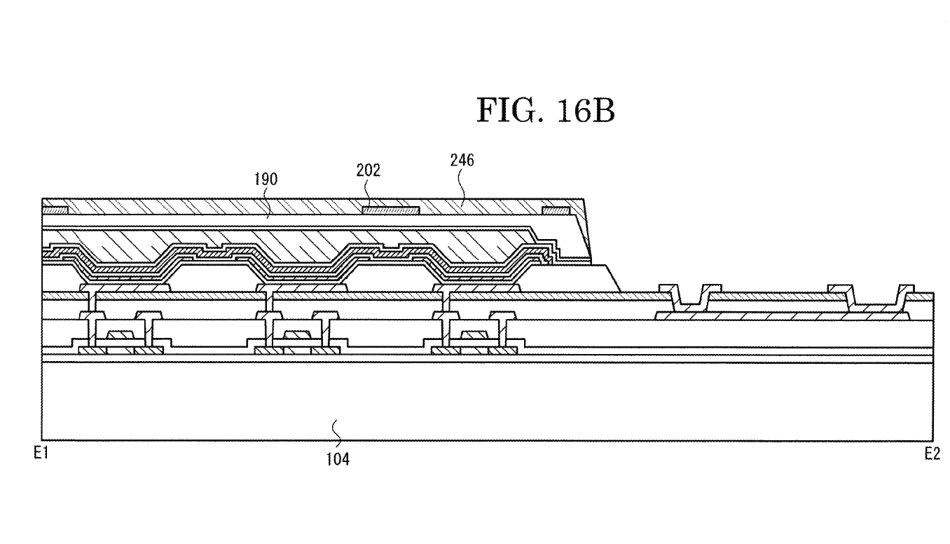

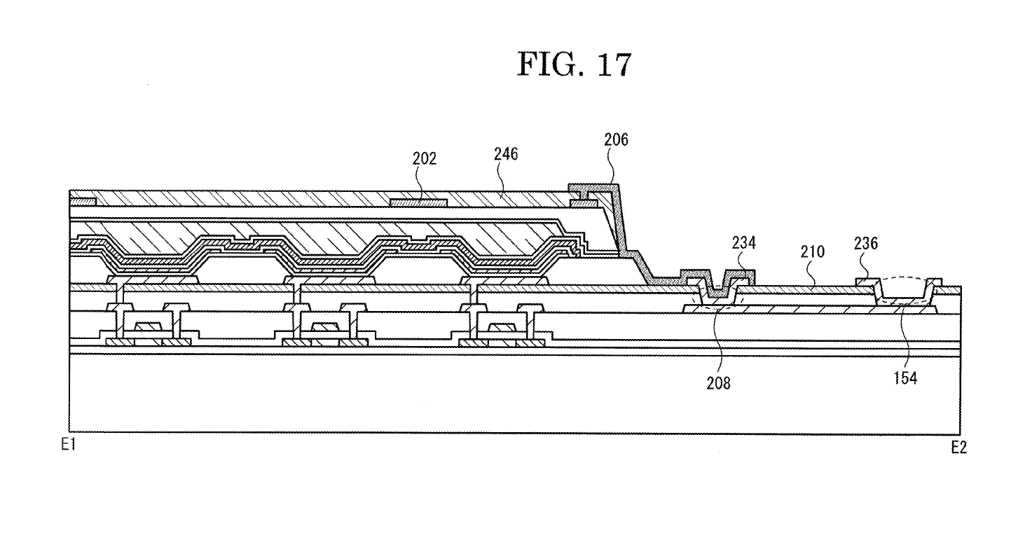

In this embodiment, a manufacturing method of the display device 100 described in the first embodiment is explained while referring to the drawings. FIG. 11A, FIG. 11B, FIG. 12A, FIG. 12B, FIG. 13A, FIG. 13B, FIG. 14A, FIG. 14B, FIG. 15A, FIG. 15B, FIG. 16A, FIG. 16B and FIG. 17 correspond to the cross section shown in FIG. 8. Explanations of the same contents as those described in the first embodiment may be omitted.

### 2-1. First Layer

As is shown in FIG. 11A, first an underlying film 106 is first formed above the substrate 104. The substrate 104 has a function for supporting a semiconductor element included in the transistor 140 or display region 102 such as the touch sensor 200 and the like. Therefore, on the substrate 104, a material having heat resistance to the temperature of processes of various elements formed on the substrate and chemical stability to chemicals used in the processes may be used. Specifically, the substrate 104 can include glass, quartz, plastic, metal or ceramic and the like.

In the case when flexibility is provided to the display device 100, a base member may be formed on the substrate 104. In this case, the substrate 104 is also called a support substrate. The base member is an insulating film having flexibility and can include a material selected from polymer materials exemplified by polyimide, polyamide, polyester and polycarbonate for example. It is possible to form the base member by applying a wet film forming method such as a printing method, an inkjet method, a spin coating method, a dip coating method or a lamination method or the like.

The underlying film 106 is a film having a function for preventing impurities such as alkali metal from diffusing from the substrate 104 (and the base member) to the transistor 140 and the like, and can include an inorganic insulator such as silicon nitride, silicon oxide, silicon nitride oxide and silicon oxynitride. Underlying film 106 can be formed having a single layer or a stacked layer structure by applying a chemical vapor deposition (CVD) method or a sputtering method or the like. In the case where the impurity concentration in the underlying film 106 is small, the underlying film 106 may not be arranged or it may be formed to cover only a part of the substrate 104.

Next, a semiconductor film 142 is formed over the substrate 104 (FIG. 11A). The semiconductor film 142 may formed from a Group 14 element such as silicon. Alternatively, the semiconductor film 142 may formed from an oxide semiconductor. A Group 13 element such as indium or gallium can be included as the oxide semiconductor, and for example, a mixed oxide (IGO) of indium and gallium can be used. In the case where an oxide semiconductor is used, the semiconductor film 142 may further include a Group 12 element, for example, a mixed oxide (IGZO) including indium, gallium, and zinc. There is no limitation to the crystallinity of the semiconductor film 142, and the semiconductor film 142 may include crystallinity out of the crystal field of a single crystal, polycrystal, microcrystal or amorphous.

In the case when the semiconductor film 142 includes silicon, the semiconductor film 142 may be formed by a CVD method using silane gas or the like as a raw material. The obtained amorphous silicon may be subjected to a heat treatment or may be crystallized by irradiation with light such as laser. In the case where the semiconductor film 142 includes an oxide semiconductor, it can be formed using a sputtering method or the like.

Next, a gate insulating film 144 is formed to cover the semiconductor film 142 (FIG. 11A). The gate insulating film 144 may have either a single layer structure or a stacked layer structure and can be formed by the same method as the underlying film 106.

Next, a gate electrode 146 is formed above the gate insulating film 144 by a sputtering method or a CVD method (FIG. 11B). The gate electrode 146 can be formed using a metal such as titanium, aluminum, copper, molybdenum, tungsten, tantalum or the like or an alloy thereof so as to have a single layer or a stacked layer structure. For example, it is possible to adopt a structure in which a metal with high conductivity such as aluminum or copper is sandwiched between metals having a relatively high melting point such as titanium, tungsten or molybdenum or the like.

Next, an interlayer film 108 is formed above the gate electrode 146 (FIG. 12A). The interlayer film 108 may have either a single layer structure or a stacked layer structure and can be formed by the same method as the underlying film 106. In the case where the interlayer film 108 has a stacked layer structure, for example, a layer including an organic compound may be formed and then a layer including an inorganic compound may be stacked.

Next, the interlayer film 108 and the gate insulating film 144 are etched to form an opening which reaches the semiconductor film 142. It is possible to form the opening by performing plasma etching in a gas including fluorine-containing hydrocarbons for example.

Next, a metal film is formed to cover the opening and etching is performed to form the source/drain electrode 148. In the present embodiment, the first terminal wiring 210 is formed at the same time as forming the source/drain electrode 148 (FIG. 12B). Therefore, the source/drain electrode 148 and the first terminal wiring 210 can exist in the same layer. The metal film can have a structure similar to the gate electrode 146 and can be formed using the same method as the gate electrode 146.

Next, the planarization film 114 is formed to cover the source/drain electrode 148 and the first terminal wiring 210 (FIG. 13A). The planarization film 114 has a function for absorbing unevenness and inclinations caused by the transistor 140, the first terminal wiring 210 and the like, and for providing a flat surface. It is possible to form the planarization film 114 using an organic insulator. High molecular materials such as epoxy resin, acrylic resin, polyimide, polyamide, polyester, polycarbonate, and polysiloxane can be used as the organic insulator and the organic insulator can be formed by the wet film formation methods described above.

Next, an inorganic insulating film 150 is formed above the planarization film 114 (FIG. 13A). As described above, the inorganic insulating film 150 functions not only as a protective film for the transistor 140 but also forms a capacitance together with the first electrode 162 of the light emitting element 160 formed later. Therefore, it is preferred to use a material having a relatively high dielectric constant. For example, it is possible to use silicon nitride, silicon nitride oxide, silicon oxynitride or the like and the first electrode 162 can be formed by applying a CVD method or a sputtering method.

Next, as is shown in FIG. 13B, the inorganic insulating film 150 and the planarization film 114 are etched using the source/drain electrode 148 and the first terminal wiring 210 as an etching stopper, and the opening 154 and the contact holes 152 and 208 are formed.

Following this, the first electrode 162 and the connection electrodes 234 and 236 are formed to cover these openings or the contact holes (FIG. 14A).

Here, since the region where the connection electrode 236 is formed, that is, the opening 154, serves as a region to which the flexible printed substrate 214 is later connected via an anisotropic conductive film or the like, the region where the connection electrode 234 is formed, that is, the area of the region where the connection electrode 234 is formed is much larger than the contact hole 208. Although in the former case, the size of the flexible printed substrate 214 varies depending on the terminal pitch or the like, for example, the width is from 10 μm to 50 μm, the length is from 1 mm to 2 mm, in the latter case an area from around several pm square to 10 μm square is sufficient. With respect to the opening 154, although miniaturization is limited due to a mounting process of the flexible printed substrate 214, the contact hole 208 may be formed to a minimum so that the pairs of conducting layers to be connected here (here, the first terminal wiring 210, the connection wiring 234 and the first wiring 206) are connected to each other with a sufficiently low contact resistance.

In the case when light emission from the light emitting element 160 is extracted from the second electrode 166, the first electrode 162 is formed to reflect visible light. In this case, a metal having high reflectivity such as silver or aluminum or an alloy thereof is used for the first electrode. Alternatively, a film of a conductive oxide having translucency is formed over the film including these metals or alloys. ITO and IZO are examples of the conductive oxide. In the case when light emission from the light emitting element 160 is extracted from the first electrode 162, the first electrode 162 may be formed using ITO or IZO.

In the present embodiment, the first electrode 162 and the connection electrodes 234 and 236 are formed above the inorganic insulating film 150. For example, the connection electrodes 234, 236 can be formed by forming a film of the metals described above to cover the opening 154 and contact holes 152, 208, then forming a film including a conductive oxide which allows visible light to pass through and then processing by performing etching. Alternatively, the conductive oxide film, the metal film, and the conductive oxide film may be sequentially stacked so as to cover the opening 154 and the contact holes 152 and 208, and then etching processing may be performed. Alternatively, a conductive oxide film, a film of the metals described above, and a conductive oxide film may be stacked in order to cover the opening 154 and the contact holes 152 and 208, and then etching processing may be performed. Alternatively, a conductive oxide may be formed so as to cover the opening 154 and the contact holes 152, 208, then stacked films of a conductive oxide film/film of the metals described above/conductive oxide film are formed so as to selectively cover the contact hole 152.

Next, a partition wall 168 is formed to cover an end part of the first electrode 162 (FIG. 14B). The partition wall 168 can absorb steps caused by the first electrode 162 and the like and electrically insulates the first electrode 162 of adjacent subpixels from each other. It is possible to form the partition wall 168 by a wet film formation method using a material which can be used for the planarization film 114 such as an epoxy resin or an acrylic resin.

Next, the functional layer 164 and the second electrode 166 of the light emitting element 160 are formed to cover the first electrode 162 and the partition wall 168 (FIG. 14B). The functional layer 164 mainly includes an organic compound and can be formed by applying a wet film formation method such as an inkjet method or a spin coating method, or a dry film formation method such as vapor deposition.

In the case when light emission from the light emitting element 160 is extracted from the first electrode 162, a metal such as aluminum, magnesium, silver or the like or an alloy thereof may be used as the second electrode 166. Conversely, in the case when light emitted from the light-emitting element 160 is extracted from the second electrode 166, a conductive oxide having translucency such as ITO may be used as the second electrode 166. Alternatively, the second electrode 166 can be formed with a thickness such that visible light can pass through the metals described above. In this case, a conductive oxide having translucency may be further stacked.

Next, a sealing film 180 is formed. As is shown in FIG. 15A, the first inorganic film 182 is formed so as to cover the light emitting element 160 and the connection electrodes 234 and 236. The first inorganic film 182 can include an inorganic material such as silicon nitride, silicon oxide, silicon nitride oxide, silicon oxynitride or the like, and can be formed by the same method as the underlying film 106.

Next, an organic film 184 is formed (FIG. 15A). The organic film 184 can include an organic resin including acrylic resin, polysiloxane, polyimide and polyester and the like. In addition, as is shown in FIG. 15A, the organic film 184 may be formed to a thickness so as to absorb irregularities caused by the partition wall 168, or to provide a flat surface. The organic film 184 is preferred to be selectively formed in the display region 102. That is, the organic film 184 is preferably formed so as not to overlap with the connection electrodes 234 and 236. It is possible to form the organic film 184 by a wet film formation method such as an inkjet method. Alternatively, the organic film 184 may be formed by forming an oligomer, which is a raw material of the polymer material, in a mist state or a gaseous state under reduced pressure, and blowing it onto the first inorganic film 182 and then polymerizing the oligomer.

Following this, a second inorganic film 186 is formed (FIG. 15A). The second inorganic film 186 has the same structure as the first inorganic film 182 and can be formed by the same method. The second inorganic film 186 can also be formed not only on the organic film 184 but also above the connection electrodes 234 and 236. In this way, it is possible to seal the organic film 184 with the first inorganic film 182 and the second inorganic film 186.

Next, the insulating film 190 is formed (FIG. 15B). The insulating film 190 can include the same material as the organic film 184 of the sealing film 180 and can be formed by the same method. As is shown in FIG. 15B, the insulating film 190 preferably selectively covers a region where the first inorganic film 182 and the second inorganic film 186 make contact with each other in the display region 102, and is formed to preferably overlap with the connection electrodes 234 and 236.

Next, the first inorganic film 182 and the second inorganic film 186 exposed from the insulating film 190 are removed by etching using the insulating film 190 as a mask (FIG. 16A). In this way, the connection electrodes 234 and 236 are exposed in the contact hole 208 and the opening 154 arranged on the outer side of the display region 102 respectively. At this time, a part of the inorganic insulating film 150 is also etched and the thickness may sometimes be reduced. The first layer 110 is formed through the above processes.

### 2-2. Second Layer

After this, a second layer including the touch sensor 200 is formed. Specifically, a first touch electrode 202 is formed above the insulating film 190 (FIG. 16B). The first touch electrode 202 can include a metal (zero-valent metal) as a main component, and examples of the metal are titanium, aluminum, molybdenum, tungsten, tantalum, chromium, copper and alloys thereof. A film including these metals or alloys is formed on almost the entire surface of the substrate 104 by a CVD method or sputtering method, then a resist is formed and etched (that is, a photolithography process), whereby the touch sensor 200 can be formed having a precise pattern as a mesh shaped wiring.

Furthermore, in the case where the first touch electrode 202 and the second touch electrode 204 exist in the same layer, the first touch electrode 202 and the second touch electrode 204 may be formed at the same time. In addition, the first touch electrode 202 and the second touch electrode 204 may be formed using a conductive oxide having translucency.

Next, an interlayer insulating film 246 is formed above the first touch electrode 202 (FIG. 16B). It is possible to form the interlayer insulating film 246 using the same material and method as the organic film 184. What is different from the planarization film 114 and the like is that a high temperature is not used, for example, when performing a baking process or the like. Since the functional layer 164 including an organic compound has already been formed at this point, it is desirable to perform the treatment at a temperature at which the organic compound does not decompose. In the case when the first touch electrode 202 and the second touch electrode 204 exist in the same layer, an interlayer insulating film 246 is formed above the first touch electrode 202 and the second touch electrode 204 so as to cover these.

Following this, an opening is formed in the interlayer insulating film 246, and the second touch electrode 204 is formed to cover the opening at the same time as when the first wiring 206 is formed. It is possible to form the opening when the interlayer insulating film 246 is formed using, for example, a photosensitive resin or the like. The first wiring 206 is formed to cover the contact hole 208, whereby the first touch electrode 202 and the first terminal wiring 210 are electrically connected (FIG. 17). It is possible to form the first wiring 206 and the second touch electrode 204 using the same method and material as the first touch electrode 202.

In the case when the first touch electrode 202 and the second touch electrode 204 exist in the same layer, an opening is formed not only for connecting the first wiring 206 and the first touch electrode 202, or the first wiring 206 and the second touch electrode 204, but an opening 244 for connecting the diamond electrodes 240 to each other is also formed in the interlayer insulating film 246. Following this, the bridge wiring 248 and the first wiring 206 are formed at the same time. Also at this time, it is possible to similarly form the first wiring 206 by applying a CVD method or a sputtering method using titanium, aluminum, molybdenum, tungsten, tantalum, chromium, copper or an alloy thereof. The second layer is formed through the above processes.

### 2-3. Other Layers

Following this, an organic protective film 266, a circularly polarizing plate 260 and a cover film 268 are formed. Next, the flexible printed substrate 214 is connected to the opening 154 using the anisotropic conductive film 252 or the like, whereby the display device 100 shown in FIG. 8 can be formed. The organic protective film 266 can be formed by applying a printing method or a lamination method or the like and can include a polymer material such as polyester, epoxy resin or acrylic resin or the like. The cover film 268 can also include a high molecular material the same as the organic protective film 266, and in addition to the high molecular materials described above, a high molecular material such as polyolefin or polyimide can also be used.

Although not shown in the diagram, in the case where flexibility is provided to the display device 100, for example, after forming the flexible printed substrate 214, after forming the circularly polarizing plate 260, or after forming the organic protective film 266, light is irradiated from the side of the substrate 104 so as to reduce the adhesive force between the substrate 104 and a base member and following this the substrate 104 may be peeled off at these interfaces using physical force.

As described in the present embodiment, the touch sensor 200 is formed by a plurality of first touch electrodes 202 and a plurality of second touch electrodes 204. Each of the plurality of first touch electrodes 202 and the plurality of second touch electrodes 204 is a mesh shaped metal wiring, and the metal wiring can be formed by a photolithography process. Therefore, it is possible to form the first touch electrode 202 and the second touch electrode 204 having a precise layout.

Each embodiment described above as embodiments of the present invention can be implemented in appropriate combination as long as they do not contradict each other. In addition, based on the display device of each embodiment, the appropriate addition, deletion, or design change of elements or the addition, deletion, or condition change of a process by a person ordinarily skilled in the art is included in the scope of the present invention as long as they possess the concept of the present invention.

In the present specification, although the case of an EL display device was mainly exemplified as a disclosed example, an electronic paper type display having other self-light emitting type display devices, liquid crystal display devices, electrophoretic elements or the like, and flat panel display devices are other application examples. In addition, the present invention can be applied from medium to small size to large size devices without any particular limitations.

Even if other actions and effects different from the actions and effects brought about by each embodiment described above are obvious from the description of this specification, or those which can be easily predicted by a person skilled in the art, it is to be understood that such actions and effects are obviously provided by the present invention.

What is claimed is:

1. A touch sensor comprising:
a substrate having flexibility; and
a plurality of touch electrodes arranged above the substrate,
wherein
each of the plurality of touch electrodes has a mesh structure,
the mesh structure includes a first conducting part and a second conducting part,
the first conducting part extends in a first direction,
the second conducting part extends in a second direction intersecting a direction orthogonal to the first direction, and
at least one angle between the first direction and the second direction is less than 90 degrees.

2. The touch sensor according to claim 1, wherein each of the plurality of touch electrodes includes a metal layer having light shielding properties.

3. The touch sensor according to claim 1, wherein the at least one angle between the first direction and the second direction is 20 degrees or more and 60 degrees or less.

4. A display device having a touch sensor comprising:
a substrate having flexibility;
a display region above the substrate and including a plurality of sub-pixels arranged in a matrix, each having a light emitting element;
an insulating layer covering the display region; and
a plurality of touch electrodes above the insulating layer,
wherein
each of the plurality of touch electrodes has a mesh structure,
the mesh structure includes a first conducting part and a second conducting part,
the first conducting part extends in a first direction,
the second conducting part extends in a second direction intersecting a direction orthogonal to the first direction,
the first conducting part and the second conducting part are arranged on the outer side of the light emitting element of each of the plurality of the sub-pixels in a plan view, and
at least one angle between the first direction and the second direction is less than 90 degrees.

5. The display device having a touch sensor according to claim 4, wherein each of the plurality of touch electrodes includes a metal layer having light shielding properties.

6. The display device having a touch sensor according to claim 4, wherein the plurality of sub-pixels includes a first sub-pixel configured to emit a first light having first wavelength spectrums, a second sub-pixel configured to emit a second light having second wavelength spectrums, and a third sub-pixel configured to emit a third light having third wavelength spectrums, and
shapes of emitting regions in at least two among the first sub-pixel, the second sub-pixel, and the third sub-pixel are different to each other.

7. The touch sensor according to claim 4, wherein the at least one angle between the first direction and the second direction is 20 degrees or more and 60 degrees or less.

8. The display device having a touch sensor according to claim 4, wherein the plurality of sub-pixels are arranged in a matrix shape in a first direction and a direction intersecting the first direction.
